(19) United States
(12) Patent Application Publication
(10) Pub. No.: US 2024/0249945 A1
(43) Pub. Date: Jul. 25, 2024

(54) CREATION OF A TRANSISTOR WITH CLOSE SILICIDE SOURCE AND DRAIN FROM THE CANAL

(71) Applicant: COMMISSARIAT A L'ENERGIE ATOMIQUE ET AUX ENERGIES ALTERNATIVES, Paris (FR)

(72) Inventors: Shay REBOH, Grenoble Cedex 09 (FR); Pablo ACOSTA ALBA, Grenoble Cedex 09 (FR); Frédéric MILESI, Grenoble Cedex 09 (FR); Laurent BRUNET, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/544,035

(22) Filed: Dec. 18, 2023

(30) Foreign Application Priority Data
Dec. 20, 2022 (FR) 22 13954

(51) Int. Cl. H01L 21/265

(52) U.S. Cl. CPC H01L 21/26586; H01L 21/26513

(57) ABSTRACT

Method for producing a metal-semiconductor alloy transistor source and drain comprising, in this order, the following steps:
providing on a substrate (100) with an insulating layer (11) and a surface semiconductor layer (12) resting on the insulating layer (11): a transistor gate block (25) on this surface semiconductor layer (12) and insulating spacers (33) on either side of said gate block (25),
amorphizing semiconductor regions (123) of said surface semiconductor layer (12) situated on either side of the gate block (25), whilst retaining at least one crystalline semiconductor zone (121) of the surface semiconductor layer (12) opposite the gate block (25),
forming selectively with respect to said crystalline zone (121) of the surface semiconductor layer, metal-semiconductor alloy regions (125) in the amorphized semiconductor regions of the surface semiconductor layer (12).

### TECHNICAL FIELD AND PRIOR ART

The present application relates to the field of methods for producing transistors, and more specifically that of forming metal-semiconductor alloy regions in particular for the transistor source and drain zones.

In methods for manufacturing transistors, so-called “silicided” zones composed of silicon and one or more metallic elements are commonly produced. The silicided zones are in particular used to form contact zones for the source and drain of transistors and improve contacts between metal pads and semiconductor source and drain regions.

The document “Characterization of fully silicided source/drain SOI UTBB nMOSFETs at cryogenic temperatures” by Yi Han et al. describes the use of a microelectronic device in which regions of a surface semiconductor layer of an SOI (Silicon On Insulator) substrate located on either side of a gate electrode are fully silicided.

One drawback of the method described is that the silicide/semiconductor junction or interface is not precisely defined.

### DISCLOSURE OF THE INVENTION

One object of the invention is to propose an improved method for producing a microelectronic device with (a) transistor(s) having metal-semiconductor alloy source and drain regions formed in the same surface semiconductor layer as that in which the channel region of said transistor(s) is provided.

The aim in particular is to achieve more precise positioning and better control of the interfaces between, on the one hand, the metal-semiconductor alloy regions formed for the source and drain and, on the other hand, the crystalline semiconductor zone in which the channel region is provided.

Thus, according to one aspect, one embodiment provides a method comprising, in this order, the following steps:
providing on a substrate with an insulating layer and a surface semiconductor layer resting on the insulating layer: a transistor gate block on this surface semiconductor layer,
amorphizing semiconductor regions of said surface semiconductor layer situated on either side of the gate block, whilst retaining at least one crystalline semiconductor zone of the surface semiconductor layer opposite the gate block,
forming metal-semiconductor alloy regions in the amorphized semiconductor regions of the surface semiconductor layer.

The inventors discovered that metal-semiconductor alloy regions formed selectively in amorphized semiconductor regions of a semiconductor structure having amorphous regions and crystalline regions.

By defining amorphous regions in advance, this selectivity makes it possible to obtain metal-semiconductor alloy regions positioned as close as possible to the channel whilst having a precisely defined and positioned interface between these regions and the crystalline semiconductor zone in which the channel is provided.

These metal-semiconductor alloy regions are formed as close as possible to the channel, in the surface layer in which the latter is provided, which can advantageously make it possible to avoid creating raised source and drain zones by epitaxial growth. In this case, the cost of the method and the thermal budget required to implement it are limited.

Advantageously, prior to the step involving amorphizing or concurrently with the step involving amorphizing said semiconductor regions: the method can comprise doping portions of the surface semiconductor layer on either side of said crystalline zone.

Such doping is typically carried out by implantation.

The semiconductor regions are advantageously amorphized by dopant implantation so as to concurrently dope the semiconductor regions of the surface semiconductor layer.

According to one possible embodiment, prior to the amorphization of the semiconductor regions, dopant implantation is carried out so as to dope so-called extension zones of the surface semiconductor layer, the insulating spacers being arranged opposite said extension zones.

According to one possible embodiment, the extension zones can be doped by implantation by means of a beam parallel to a normal to a main plane of the substrate and prior to a step involving forming insulating spacers on either side of the gate block, the amorphization of the semiconductor regions being carried out after the formation of the insulating spacers.

Alternatively, said extension zones can be doped after the formation of said insulating spacers on either side of said gate block, by implantation with a beam inclined relative to a normal to a main plane of the substrate.

The method can also comprise, after doping said portions of the surface semiconductor layer and the step involving amorphizing said semiconductor regions at least one activation annealing of dopants provided so as not to recrystallize, in particular not to render polycrystalline or monocrystalline, said amorphized semiconductor regions.

This avoids the need for further amorphization in order to then selectively form the metal-semiconductor alloy regions in the amorphous regions.

According to another possible embodiment, the method can also comprise, after doping said portions of the surface semiconductor layer and the step involving forming said metal-semiconductor alloy regions, at least one activation annealing of dopants. In this case, it is advantageous to postpone the activation annealing of dopants so as not to risk recrystallizing the amorphized regions.

According to one particular embodiment, the step involving amorphizing said semiconductor regions comprises implantation with a beam inclined relative to a normal to a main plane of the substrate. This can enable the metal-semiconductor alloy regions to be produced in a zone very close to the channel.

The substrate is advantageously provided with one or more components of a first level of components formed in an underlying semiconductor layer. The method is thus particularly suited to producing 3D devices or circuits having several superimposed semiconductor layers and several levels of components produced in these layers.

In particular, the fact that it is possible to avoid carrying out one or more epitaxy steps to form raised source and drain regions means that the thermal budget is more compatible with the use of 3D circuits or devices.

According to one particular embodiment, one or more contact pads can be produced directly on metal-semiconductor alloy regions formed in the surface layer. Thus, according to one embodiment, the method can also comprise steps involving:
forming at least one insulating layer on the metal-semiconductor alloy regions and the gate,
making at least one opening revealing at least one given region among said metal-semiconductor alloy regions,
forming a conductive pad in contact with said given region.

Advantageously, with the formation of the metal-semiconductor alloy regions formed in the surface layer, it is possible to avoid having to carry out an epitaxy step of raised source and drain regions before producing the conductive pad.

### BRIEF DESCRIPTION OF THE DRAWINGS

The present invention will be better understood in light of the following description and the appended drawings wherein:

FIGS. 1A and 1B show a method for selectively producing metal-semiconductor alloy regions in amorphous regions formed in the surface layer of a semiconductor-on-insulator type substrate.

FIG. 2 shows a particular exemplary embodiment in which the amorphous regions are produced by implantation on either side of insulating spacers against a gate block.

FIGS. 3A and 3B show another particular exemplary embodiment in which the amorphous regions are produced by implantation by means of an inclined beam.

FIG. 4 shows a particular exemplary embodiment in which the substrate on which the amorphization and selective silicidation of amorphized regions of a surface semiconductor layer is carried out already has a level of components formed in another underlying semiconductor layer.

FIG. 5 shows a particular exemplary embodiment in which access zones under the spacers are also doped.

FIG. 6 shows another exemplary embodiment in which the amorphization is carried out after doping access zones and forming spacers on either side of the gate block.

FIGS. 7A and 7B show an exemplary embodiment in which dopant activation is carried out after forming metal-semiconductor alloy regions.

FIG. 8 shows activation of dopants implanted in amorphous semiconductor regions, the activation being carried out without recrystallization of these regions.

FIGS. 9A to 9E show the production of contact pads directly on the metal-semiconductor alloy regions formed in the same surface semiconductor layer as that in which the transistor channel region is formed.

Moreover, in the description below, terms related to the orientation of a structure such as “front”, “upper”, “back”, “lower”, “side”, are to be understood considering that the structure is oriented as shown in the figures.

### DETAILED DISCLOSURE OF PARTICULAR EMBODIMENTS

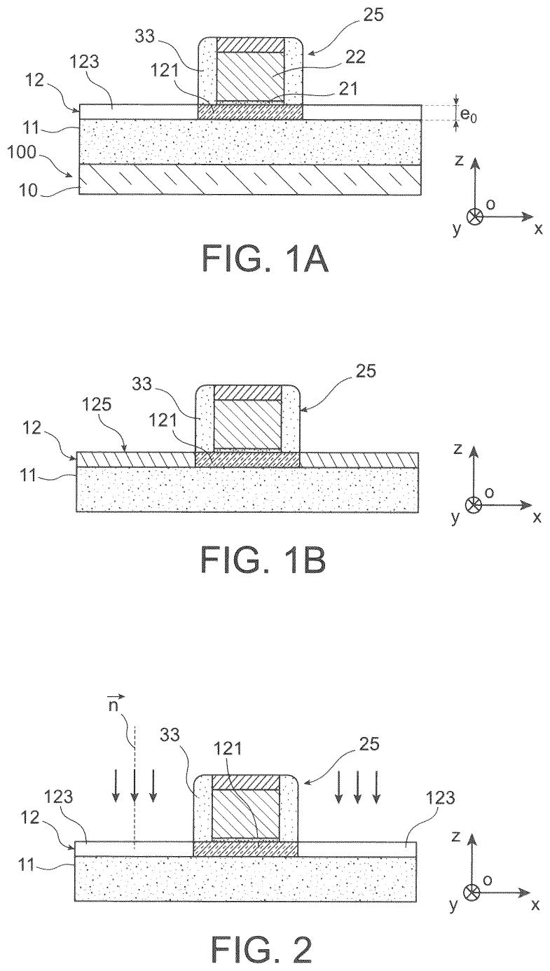

A possible starting structure for the implementation of metal-semiconductor alloy transistor source and drain regions is shown in FIG. 1A.

This structure comprises a substrate 100 with an insulating layer 11, for example made of SiO₂, and commonly known as BOX (buried oxide), the insulating layer 11 itself being coated with a surface semiconductor layer 12 in which one or more transistors are intended to be formed.

The surface semiconductor layer 12, for example made of silicon, is provided with a thickness that may be comprised, for example, between 5 nm and 100 nm, advantageously between 5 and 20 nm.

The substrate 100 on which the insulating layer 11 rests can be, for example, a semiconductor layer, the structure being in this case made from a semiconductor-on-insulator type substrate, for example SOI type (silicon-on-insulator). The transistor or transistors formed can then be provided using FDSOI (Fully Depleted Silicon On Insulator) technology.

In the exemplary embodiment shown, the structure also has a gate block 25. This block 25 is formed here of a gate dielectric region 21, for example made of SiO₂ or HfO₂, topped by a gate region 22 formed of one or more layers of gate material, for example made of polysilicon or TiN or W, or a stack of at least several of these materials. Spacers 33 are formed on either side of the gate block 25. These spacers 33 can, for example, be made of SiN or SiBCN or SiOCN.

The surface semiconductor layer 12 is provided here with regions 123 of amorphous semiconductor material, for example amorphous silicon, while a zone 121 of crystalline semiconductor material, for example crystalline silicon, is preserved opposite the gate block 25. In this example, this zone of crystalline semiconductor material extends opposite at least some of the insulating spacers 33. A crystalline zone of the semiconductor layer 12 in which the transistor channel and at least some of the extension zones are located is thus preserved.

The amorphous regions 123 can extend, as shown in FIG. 1A, over the entire thickness e₀ of the semiconductor layer 12.

Metal-semiconductor alloy regions 125 are then produced (FIG. 1B) in the amorphous semiconductor regions 123 on either side of the semiconductor zone 121. The regions 125 are in particular silicide-based zones when the surface semiconductor layer 12 is made of silicon. The metal-semiconductor alloy regions 125 are preferably produced at a temperature of less than 600° C. and advantageously less than 500° C. To do this, a sputtering method can, for example, be used to deposit a metal material. Such a method uses one or more targets from which the element or elements to be deposited is or are extracted. A particular example of this method involves silicidation. Silicidation involves a metal deposit that is heated to react with the semiconductor layer to form a silicide. Metal can then be selectively removed from the alloy created. Zones of NiPtSi can be formed in amorphous silicon regions, for example, by silicidation at a temperature of around 400° C.

Thanks to the prior amorphization of certain regions 123 of the surface semiconductor layer 12, the boundary of the metal-semiconductor alloy regions 125 formed in these amorphous regions is better defined and the arrangement of these metal-semiconductor alloy regions 125 is better controlled with respect to the channel zone of the transistor.

The amorphous regions 123 in which the metal-semiconductor alloy regions are formed are typically formed by means of one or more amorphization implantations.

In the example shown in FIG. 2, the amorphization implantation(s) is (are) carried out parallel to a normal n to a main plane of the substrate 100 (i.e. a plane of the substrate parallel to the plane [O°; x°; y] of an orthogonal reference frame [O°; x°; y°; z] given in FIG. 2). The amorphization implantation(s) is (are) preferably carried out here after having formed insulating spacers 33 on either side of the gate block 25. This can then prevent the silicidation being too close to the canal zone and encroaching on this zone.

Insofar as it is possible here to produce fully silicided source and drain regions with reduced resistances, the amorphization implantation(s) can be carried out here without having to control the crystalline thickness to be maintained in the surface semiconductor layer 12.

Amorphization can advantageously be carried out over the entire thickness of the semiconductor layer 12 until it reaches the insulating layer 11 and is in contact with it. Ion implantation, for example of Si+ ions, with dose and energy conditions determined by simulation and verified experimentally by TEM (transmission electron microscopy) imaging, can be used to amorphize a given thickness of a silicon layer. Simulation tools based on a Monte Carlo method, in particular of the TRIM type (“Transport of Ions in Matter”) and/or KMC (“Kinetic Monte Carlo”). For example, a Ge+ ion implantation with a dose (or fluence) of 5.0×10¹⁴ ions*cm⁻² and an energy of 7 keV can produce an amorphous thickness of around 11 nm.

If doping is provided during the same ion implantation, dopant ions can be used for silicon, such as phosphorus or arsenic for n-type doping or boron for p-type doping.

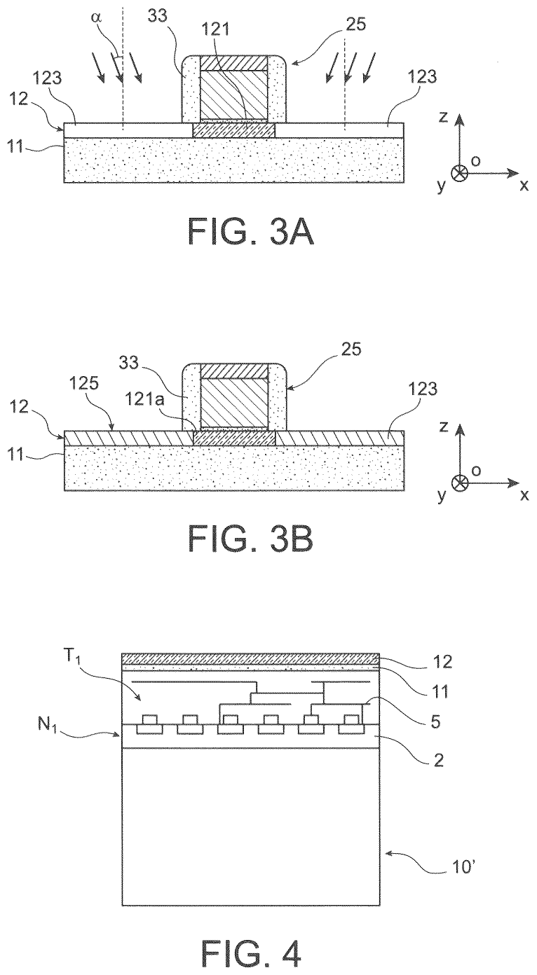

As an alternative to the exemplary embodiment described above, in order to produce the amorphous semiconductor regions 123, it is possible to carry out, as shown in FIG. 3A, at least one amorphization implantation with an inclined beam, i.e. with a non-zero angle α of the beam of implanted species with respect to a normal n to a principal plane of the substrate. In this case, the amorphous semiconductor regions 123 can partially extend opposite the insulating spacers 33.

The amorphization implantation and in particular the angle of the beam can be provided so as to preserve a crystalline zone 121 opposite the spacers 33.

This then produces, as shown in FIG. 3B, metal-semiconductor alloy regions 125 that partially extend under the spacers 33 whilst preserving a non-silicided zone 121a opposite the spacers.

According to another alternative embodiment, a method as described above can be used on a different substrate. In particular, the starting structure of the method can be as in the particular exemplary embodiment shown in FIG. 4. The surface semiconductor layer 12 and the insulating layer 11 rest here on a substrate that already has a first level N₁ of components, for example transistors.

Thus, one or more transistors T₁ of a first level N₁ of components are, in the exemplary embodiment shown, partly formed in an underlying semiconductor layer 2. The transistors T₁ of the first level N₁ are covered here by one or more metallic interconnection stages formed in one or more insulating layers, typically a stack 5 of insulating layers, for example made of SiO₂. The stack 5 of insulating layers is provided with or covered by the insulating layer 11 of buried oxide, this insulating layer 11 itself being covered by the surface semiconductor layer 12.

The method described above can then be applied to produce one or more second level transistors and in particular to form metal-semiconductor alloy regions for the second level transistor source and drain zones.

Prior to the production of the metal-semiconductor alloy regions 125 described above, it is possible to carry out doping of zones of the semiconductor layer 12 on either side of the gate block 25 and in particular doping of extension zones 122 located on either side of the gate opposite the insulating spacers 33.

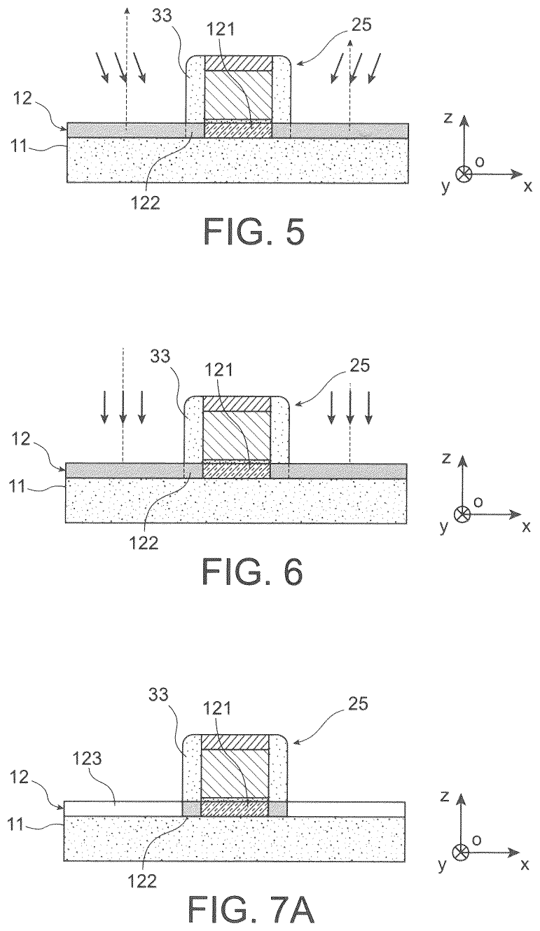

Thus, in the exemplary embodiment shown in FIG. 5, at least one dopant implantation is carried out by means of a beam inclined relative to a normal n to a main plane of the substrate 100 in order to carry out doping under the insulating spacers 33. The implantation conditions depend on the dopant species used and the inclination provided. For example, for n-doping with phosphorus, if an implantation is carried out at an inclination of 7°, a critical dose of around 1*10¹⁴ at/cm² can be used. For example, it is possible to carry out implantation with doses typically less than 2*10¹⁴ at/cm² and advantageously less than 1*10¹⁴ at/cm². Another option for not amorphizing the implanted layer is to carry out hot implantation, typically at a temperature greater than 400° C. In this case, the implantation dose limit is less restrictive. This dopant implantation can be provided at a low dose, without amorphizing the surface semiconductor layer 12.

The method typically also comprises a step of activation annealing of the dopants. This annealing can be conventional annealing, for example rapid thermal annealing, or may be carried out by means of a laser. If 3D integration is not involved, with the use of a device having several superimposed semiconductor layers, annealing can be carried out at a temperature of around 1000° C. to 1100° C. for several seconds. If 3D integration is involved, where there are several levels of superimposed components and/or semiconductor layers, “millisecond” laser annealing may be preferred to bring the structure up to the indicated temperatures of 1000° C. to 1100° C., but for a duration of several tens of milliseconds.

Amorphization and silicidation can then be carried out as described above.

Alternatively or in combination with the exemplary embodiment described above, regions on either side of the gate block 25 can be doped and amorphized simultaneously by implantation.

According to one particular exemplary embodiment, P+ ion implantation with a dose of 1.5×10¹⁵ ions*cm⁻² at an energy of 4 keV can be carried out in order to amorphize and dope a silicon layer with a thickness of 12 nm.

Implantation by means of an inclined beam can then be used. In order to avoid carrying out amorphization too close to the channel zone of the transistor, it can alternatively be provided to carry out concurrent amorphization and doping by implantation at a high dose, for example comprised between 5×10¹⁴ ions*cm⁻² and 1.0×10¹⁶ ions*cm⁻² or of around 1.5×10¹⁵ ions*cm⁻², with a non-inclined beam parallel to a normal to the main plane of the substrate.

In this case, extension zones under the spacers 33 are also doped by implantation at a lower dose and possibly with another doping species in order to avoid amorphization too close to the channel zone.

In the exemplary embodiment shown in FIG. 6, the concurrent doping and amorphization is carried out while the extension zones 122 under the spacers 33 have already been doped beforehand.

The implantation conditions as described above can, for example, be used.

The doping step(s), and in particular the step(s) of doping zones 122, are typically followed by at least one activation annealing of dopants.

The method typically also comprises a step of activation annealing of the dopants. This annealing can be conventional annealing, for example rapid thermal annealing, or may be carried out by means of a laser.

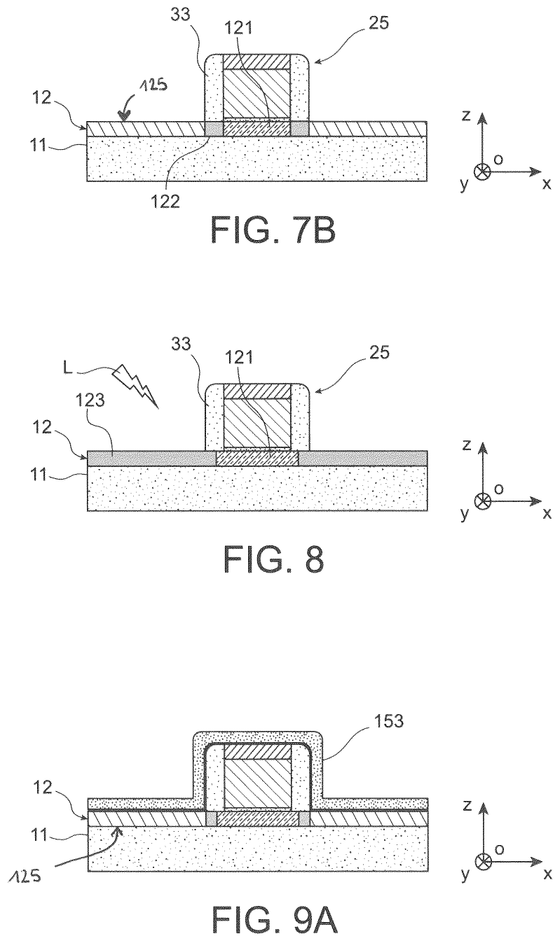

In the exemplary embodiment shown in FIGS. 7A-7B, first of all

(FIG. 7A) the extension zones are doped and the regions 123 on either side of the spacers are amorphized and doped.

Then (FIG. 7B), the metal-semiconductor alloy regions 125 are formed. The activation annealing of dopants can then be carried out.

In an alternative embodiment shown in FIG. 8, after having amorphized semiconductor regions 123 which have also been doped, activation annealing, for example by means of a laser L, is carried out. The annealing is advantageously provided, particular in terms of laser exposure time, so as to preserve the amorphous nature A of the semiconductor regions 123.

Annealing can be carried out, for example, by means of a laser with a wavelength in the UV range and in the form of pulses typically lasting between 10 and 1000 nanoseconds. The use of a laser operating in pulsed mode makes it possible to limit the thermal budget. The wavelength of the laser L, the pulse duration of the laser beam and preferably the energy density of the laser beam are chosen so as to enable activation without recrystallizing the amorphized regions 123.

A particular melting/resolidification mode by laser annealing with a sufficient resolidification speed to obtain a layer with an amorphous-type structure can in particular be used.

For an initial layer of silicon with a thickness of around 28 to 32 nm that has been fully amorphized by ion implantation, laser annealing with a laser having a wavelength of 308 nm and a pulse duration between 100 ns and 200 ns carried out with an energy density of 0.7 J/cm²+/−0.05 produces the desired layer.

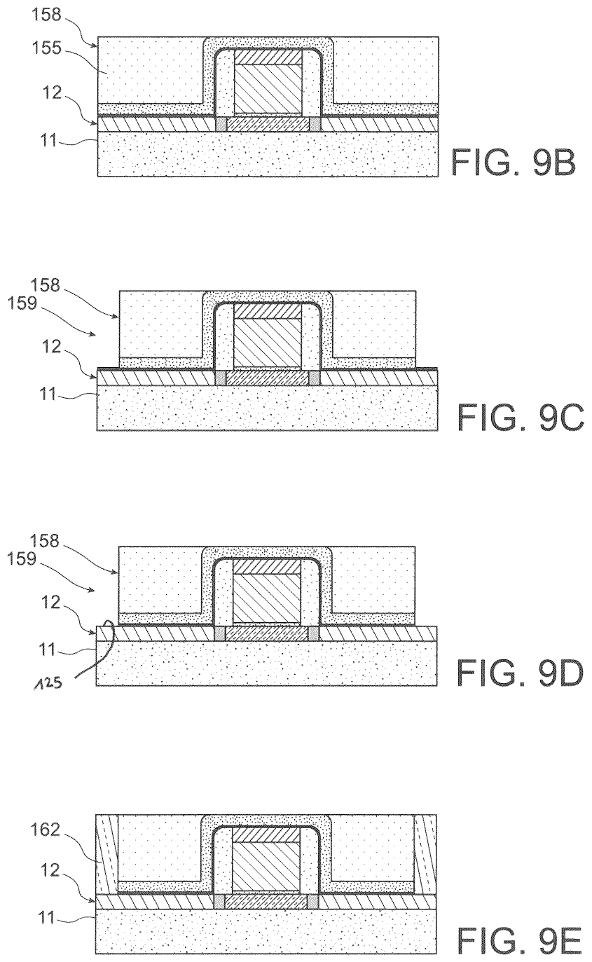

In the exemplary embodiment shown in FIGS. 9A-9E, after having produced the metal-semiconductor alloy regions 125, contact pads 162 are formed on these regions 125.

To do this, an insulating mask 158 is first formed.

The production of the insulating mask 158 can, as in FIG. 9A, comprise the formation of an insulating layer 153 here by deposition, for example, of silicon nitride (SiN).

A deposition of oxide 155, for example of the FOX (field oxide) type, followed by a step of planarization (FIG. 9B), typically chemical mechanical planarization, can then be carried out.

Then (FIG. 9C), openings 159 are made on either side of the gate block 25, for example by etching until the thin insulating layer 151 is reached. The openings 159 are then extended (FIG. 9D) until the metal-semiconductor alloy regions 125 are reached.

A conductive material 162 is then deposited (FIG. 9E) in the openings, in particular a metal such as W.

In any of the exemplary embodiments described above, the metal-semiconductor alloy regions are advantageously formed directly in the surface semiconductor layer 12 on which the gate block rests without an intermediary epitaxy step being carried out to form raised source and drain regions. In this case, one advantage of the method is that it costs less and has a lower thermal budget.

Although requiring an additional step of epitaxial growth, it is alternatively possible to carry out the selective silicidation on amorphous regions of source and drain semiconductor blocks known as “raised”, i.e. located above the upper face of the surface semiconductor layer 12 in which the channel zone of the transistor is provided.

In any of the exemplary methods described above, the metal-semiconductor alloy regions are typically produced from a silicon layer. It is also possible to selectively produce metal-semiconductor alloy regions in amorphized regions of a semiconductor material other than silicon, for example Si₁₋ₓGeₓ (where x>0).

1. A method for manufacturing at least one transistor structure, comprising, in this order, the following steps:
providing on a substrate (100) having an insulating layer (11) and a surface semiconductor layer (12) resting on the insulating layer (11): a transistor gate block (25) on this surface semiconductor layer (12) and insulating spacers (33) on either side of said gate block (25),
amorphizing semiconductor regions (123) of said surface semiconductor layer (12) situated on either side of the gate block (25), whilst retaining at least one crystalline semiconductor zone (121) of the surface semiconductor layer (12) below the gate block (25),
forming, in particular selectively with respect to said crystalline zone (121) of the surface semiconductor layer, metal-semiconductor alloy regions (125) in the amorphized semiconductor regions of the surface semiconductor layer (12),
the method also comprising, prior to the step involving amorphizing or concurrently with the step involving amorphizing said semiconductor regions (123):
doping portions (122, 123) of the surface semiconductor layer (12) on either side of said crystalline zone (121),
the method further comprising:
after doping said portions (122, 123) of the surface semiconductor layer and the step involving amorphizing said semiconductor regions (123): at least one activation annealing of dopants provided so as not to recrystallize said amorphized semiconductor regions (123).

2. The method according to claim 1, wherein the step involving amorphizing said semiconductor regions (123) is carried out by ion implantation and so as to concurrently dope said semiconductor regions (123) of the surface semiconductor layer (122).

3. The method according to claim 1, wherein prior to the step involving amorphizing said semiconductor regions (123), implantation is carried out so as to dope so-called extension zones (122) of the surface semiconductor layer (12), the insulating spacers (33) being arranged opposite said extension zones (122).

4. The method according to claim 3, wherein said extension zones (122) are doped by implantation by means of a beam parallel to a normal (n) to a main plane of the substrate (100) and prior to a step involving forming insulating spacers (33) on either side of said gate block (25), the step involving amorphizing the semiconductor regions (123) being carried out after the formation of said insulating spacers (33).

5. The method according to claim 3, wherein said extension zones (122) are doped after the formation of said insulating spacers (33) on either side of said gate block (25), by implantation with a beam inclined relative to a normal (n) to a main plane of the substrate (100).

6. The method according to claim 1, wherein the step involving amorphizing said semiconductor regions (123) comprises implantation with a beam inclined relative to a normal (n) to a main plane of the substrate (100).

7. The method according to claim 1, wherein the substrate (100) is provided with one or more components of a first level (N1) of components formed in an underlying semiconductor layer (2).

8. The method according to claim 1, further comprising steps involving:
forming at least one insulating layer on the metal-semiconductor alloy regions (125) and the gate,
making at least one opening exposing at least one given region among said metal-semiconductor alloy regions (125),
forming a conductive pad in contact with said given region.

9. A method for manufacturing at least one transistor structure, comprising, in this order, the following steps:
providing on a substrate (100) with an insulating layer (11) and a surface semiconductor layer (12) resting on the insulating layer (11): a transistor gate block (25) on this surface semiconductor layer (12) and insulating spacers (33) on either side of said gate block (25),
amorphizing semiconductor regions (123) of said surface semiconductor layer (12) situated on either side of the gate block (25), whilst retaining at least one crystalline semiconductor zone (121) of the surface semiconductor layer (12) below the gate block (25),
forming, in particular selectively with respect to said crystalline zone (121) of the surface semiconductor layer, metal-semiconductor alloy regions (125) in the amorphized semiconductor regions of the surface semiconductor layer (12), the method also comprising, prior to the step involving amorphizing or concurrently with the step involving amorphizing said semiconductor regions (123):
doping portions (122, 123) of the surface semiconductor layer (12) on either side of said crystalline zone (121),
the method further comprising:
after doping said portions (122, 123) of the surface semiconductor layer and the step involving forming said metal-semiconductor alloy regions (125), at least one activation annealing of dopants.

10. The method according to claim 9, wherein the step involving amorphizing said semiconductor regions (123) is carried out by ion implantation and so as to concurrently dope said semiconductor regions (123) of the surface semiconductor layer (122).

11. The method according to claim 9, wherein prior to the step involving amorphizing said semiconductor regions (123), implantation is carried out so as to dope so-called extension zones (122) of the surface semiconductor layer (12), the insulating spacers (33) being arranged opposite said extension zones (122).

12. The method according to claim 11, wherein said extension zones (122) are doped by implantation by means of a beam parallel to a normal (n) to a main plane of the substrate (100) and prior to a step involving forming insulating spacers (33) on either side of said gate block (25), the step involving amorphizing the semiconductor regions (123) being carried out after the formation of said insulating spacers (33).

13. Method according to claim 11, wherein said extension zones (122) are doped after the formation of said insulating spacers (33) on either side of said gate block (25), by implantation with a beam inclined relative to a normal (n) to a main plane of the substrate (100).

14. Method according to claim 9, wherein the step involving amorphizing said semiconductor regions (123) comprises implantation with a beam inclined relative to a normal (n) to a main plane of the substrate (100).

15. Method according to claim 9, wherein the substrate (100) is provided with one or more components of a first level (N1) of components formed in an underlying semiconductor layer (2).

16. Method according to claim 9, also comprising steps involving:
forming at least one insulating layer on the metal-semiconductor alloy regions (125) and the gate,
making at least one opening exposing at least one given region among said metal-semiconductor alloy regions (125),
forming a conductive pad in contact with said given region.
